(19) United States
(12) Patent Application Publication
(10) Pub. No.: US 2013/0014700 A1
(43) Pub. Date: Jan. 17, 2013

(54) TARGET SHIELD DESIGNS IN MULTI-TARGET DEPOSITION SYSTEM.

(71) Applicant: Hariharakeshava Sarpangala Hegde, Fremont, CA (US)

(72) Inventor: Hariharakeshava Sarpangala Hegde, Fremont, CA (US)

(21) Appl. No.: 13/180,466

(22) Filed: Jul. 11, 2011

(51) Int. Cl. C23C 14/34

(52) U.S. Cl. 118/723 R

(57) ABSTRACT

A multi-target deposition arrangement comprising of a target assembly turret configured to be rotatable is provided. The arrangement also includes a plurality of targets mounted on the target assembly turret, wherein a first target is positioned in an operational position, which is facing a substrate during sputtering. The arrangement further includes a shield arrangement that includes at least a set of static shields and a set of dynamic shields. The set of static shields is attached to the target assembly turret. The set of dynamic shields is aligned with the set of static shields when the first target is rotated into the operational position for sputtering, wherein the shield arrangement prevents cross contamination to other targets when the sputtering is occurring to the first target.

### BACKGROUND OF THE INVENTION

A combination of static and dynamic shielding is disclosed that prevents cross contamination in a multi-target long throw remote plasma based deposition process. In particular, special static shields with innovative features to allow rotate/index of sputter targets at extreme target tilt angle ranges are disclosed.

Long-throw remote plasma based deposition processes have long been employed for plasma processing of substrates (e.g., wafers, flat panel displays, portable device displays, etc.). In a long-throw plasma based deposition process, a plasma source, such as an ion source, is positioned some distance away from the target while bombarding the target with ions. The ions from the plasma source sputter material off the target, which causes the sputtered material to be deposited on the surface of a substrate.

To elaborate, the term “long throw” refers to the fact that the target is located typically (but not always necessarily) at least one wafer diameter away from the wafer. Long-throw plasma based deposition is particularly suitable for applications where extremely tight uniformities are required across the wafer, or when excellent step coverage of features are desired. Multi-target long-throw plasma based deposition employs multiple targets whereby a specific target can be moved or rotated in place for sputtering when called for by the recipe.

FIG. 1 shows a prior art arrangement for performing long throw deposition wherein the target angle can be tilted to improve deposition uniformity and film properties such as stress hardness, electrical conductivity, etc. Referring now to FIG. 1, there is shown a port 102 representing the opening into which the opening of a plasma source may be fitted. The plasma source may generate plasma from, for example, RF energy via an inductive coil. The plasma source is omitted in FIG. 1 to simplify discussion since the plasma source itself is not a central feature of the present invention.

The ions from the plasma travel toward target 104 to sputter material off the surface of target 104 for deposition on a wafer.

In the example of FIG. 1, the shutter is shown open; and the wafer may be mounted to tilt-and-rotate fixture 110 such that when plasma is generated in the plasma source and ions from the plasma sputter material off the surface of target 104, the sputtered material would cause deposition to occur on the surface of the wafer. Target 104 is tiltable and rotatable in order to facilitate tuning of the deposition process and parameters. For example, the thickness uniformity of the film on the wafer and/or the etch rate from the target may be changed, and/or film stress may be changed, by tilting the target at an appropriate angle. As another example; the etch rate may change depending on the tilt angle of the target.

In the prior art, there exist multi-target systems wherein multiple targets formed of the same or different materials may be mounted on a rotatable turret. The rotatable targets form what is commonly known as a target assembly turret with different targets being set at different tilt angles. The target assembly turret is rotatable to rotate (or index) the target into the appropriate position for use. Generally speaking, only one target is exposed to the ions from the plasma at any given time for sputtering purposes while the other targets are shielded from the plasma.

As mentioned earlier, different targets may be formed of different materials. As such, it is important to keep the cross-contamination of target materials among different targets to a minimum during deposition. Cross contamination may occur when a target is rotated or indexed into position for sputtering and inadequate shielding allows material sputtered from that target to be splattered or deposited onto a neighboring target of the target assembly turret. Cross contamination is highly undesirable since a target contaminated with materials from its neighbor target may cause unintended material deposition on the substrate surface, resulting in defective devices on the wafer.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows a prior art arrangement for performing long throw deposition

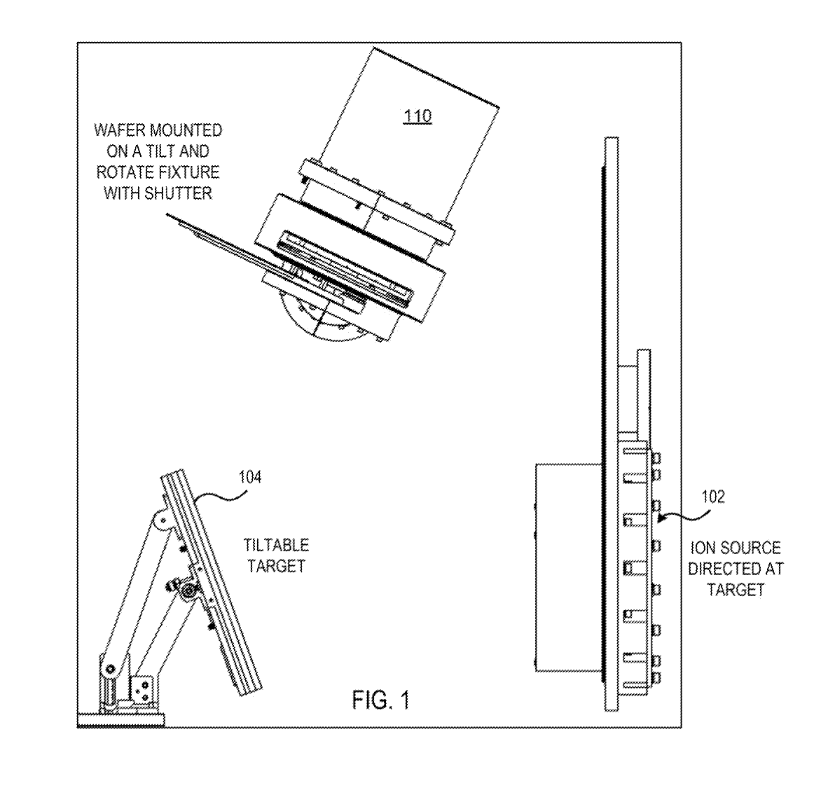

FIG. 2 shows an example target assembly turret having six targets to facilitate discussion.

FIG. 3 shows, in accordance with an embodiment of the invention, the static and dynamic shields.

FIG. 4 shows, in accordance with an embodiment of the invention, relevant portions of the deposition system including the innovative static and dynamic shields.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

The present invention relates to improved shielding arrangements, including a combination of dynamic and static shields, for simultaneously minimizing the size of the chamber and improving cross contamination avoidance. In one or more embodiments, the static shield pieces are designed such that when a target is rotated (or indexed—the terms being synonymous herein) into position for sputtering, two especially designed dynamic shields are aligned with the two especially designed static shield pieces, thereby forming a tight seal to prevent cross contamination to other targets of the target assembly turret during sputtering.

The two especially designed static shield pieces are, in one or more embodiments of the invention, provided with optional cutouts to accommodate the extreme tilt angles of the target during indexing. By providing the optional cutouts, it is possible to index the target even when the target is tilted beyond the coverage of the dynamic shield piece. In this manner, the dynamic shield piece may be made as small as possible to minimize the size of the target cover housing while preventing damage to the target during indexing if the target happens to be tilted at an extreme angle while being indexed. In one or more embodiments, the size and location of each optional cutout is such that cross contamination from target to target of the target assembly turret is substantially minimized.

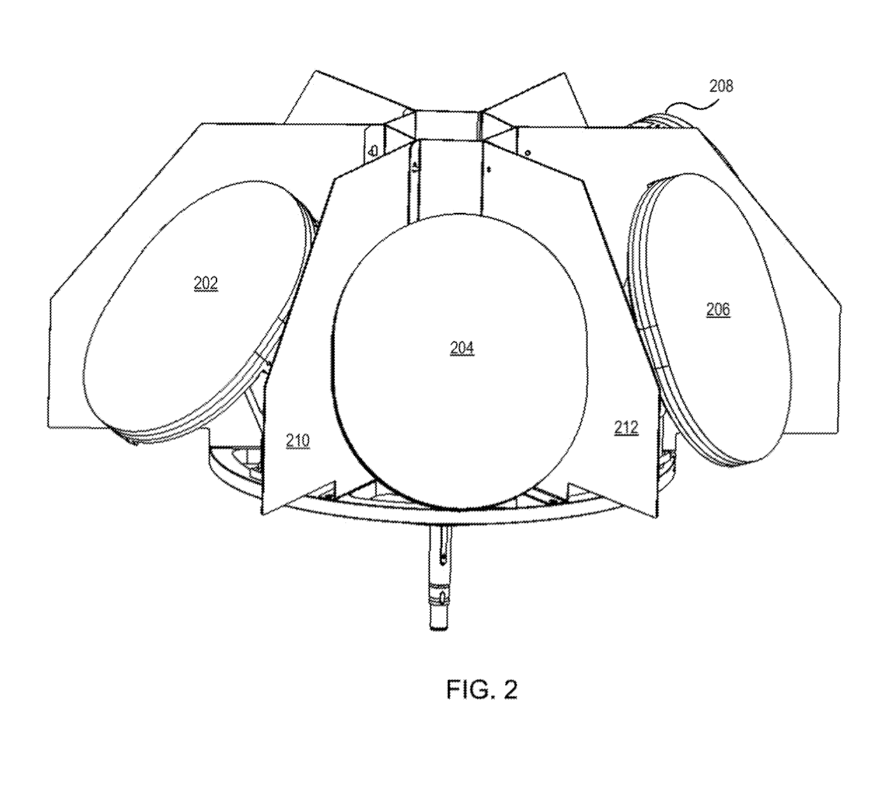

The features and advantages of the invention may be better understood with reference to the figures and discussions that follow. FIG. 2 shows an example target assembly turret having six targets, of which four targets 202, 204, 206 and 208 are shown. Each of the six targets may be formed of a similar material or of different materials. Further, each target may be pre-tilted or dynamically tilted during use at a specific angle in the target assembly turret.

During deposition, only one target (i.e., the target currently employed for sputter deposition purpose) is positioned facing the source and the wafer. The other targets are shielded, at least partially, by the dynamic shield pieces that exist between the neighboring targets. As the terms are employed herein, dynamic shield pieces refer to shield structures that rotate or index along with the targets when the targets are rotated or indexed. In contrast, static shield pieces refer to shield structures that are stationary even when the targets are rotated.

For example, neighboring targets 202 and 206 are shielded from cross contamination that may originate from neighboring target 204 during deposition by the use of dynamic shields 210 and 212. As shown in the example of FIG. 2, dynamic shields 210 and 212 are positioned vertically relative to the rotational plane of the target turret assembly to reduce splattering.

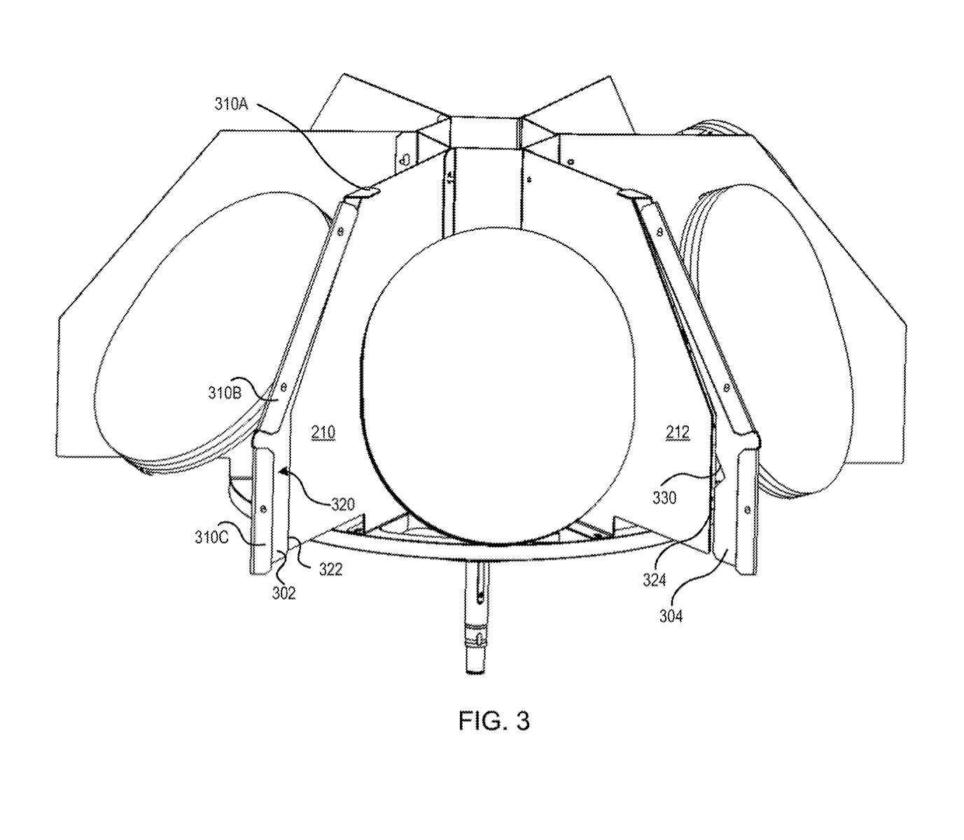

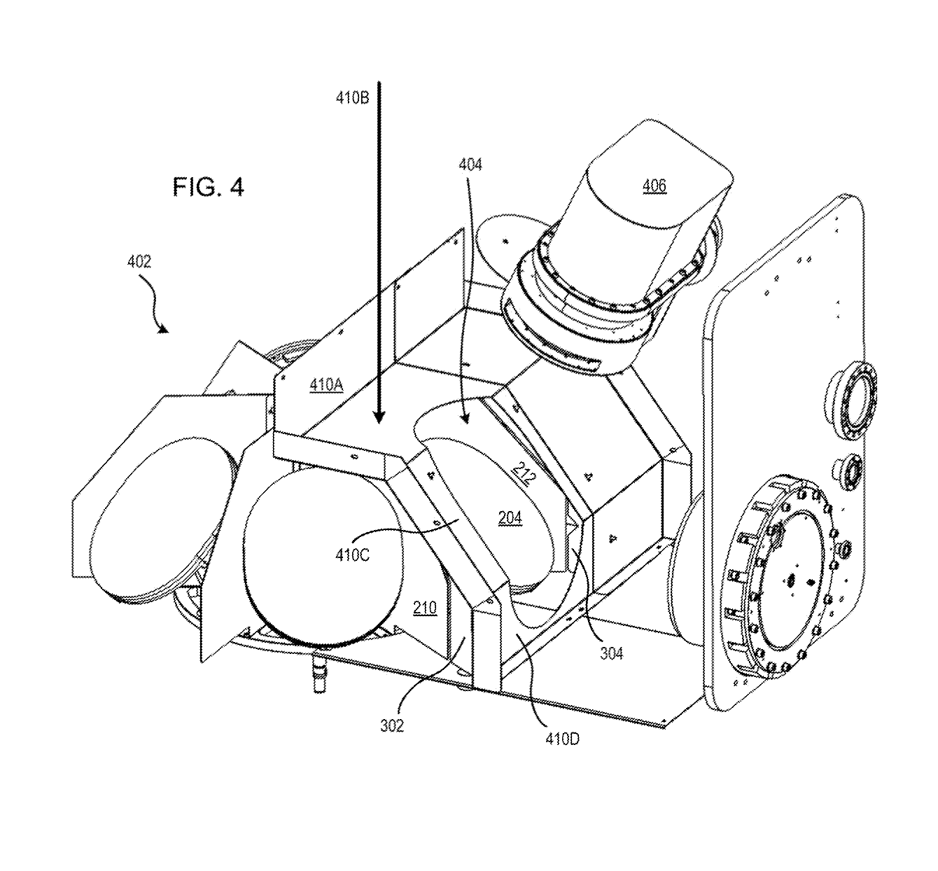

FIG. 3 shows, in accordance with an embodiment of the invention, static shields 302 and 304, which are integrated with the target cover housing such that static shields 302 and 304 remain stationary when the target assembly turret with its targets and dynamic shields rotate to index individual targets into position for sputtering. In the example of FIG. 3, static shield 302 includes a plurality of flanges 310A, 310B and 310C to facilitate fastening or attaching static shield 302 to the surface(s) of the target cover housing. Although three flanges are shown, a greater or fewer numbers of flanges may be employed. Any suitable and/or conventional method of attachment of the flanges to the target cover housing may be employed. The goal is to attach the static shields to the target cover housing (an example of which is shown in FIG. 4) and the exact method of attachment is not central to embodiments of the invention herein.

Each of static shields 302 further includes an optional cutout 320, which is shaped and dimensioned to allow the target assembly turret to rotate even when the target that is recently employed for sputter deposition is tilted at an extreme angle prior to or during indexing. When such target is tilted at an extreme angle, it is possible that the bottom part of that target (such as target 204 of FIG. 2) juts or protrudes out beyond the plane formed by edge 322 of dynamic shield 210 and edge 324 of dynamic shield 212. If optional cutouts 320 and 330 were not provided in static shields 302 and 304 respectively, the dynamic shields 210 and 212 would have to be made much larger to prevent damage to the extreme tilt target 204 when the target assembly turret rotates to index extreme tilt target 204 away from the operational position and to index another target into the operational position for sputtering.

In one or more embodiments, the size of each optional cutout is dimensioned such that it provides just sufficient clearance for target assembly turret rotation, even when the recently-employed target is at an extreme tilt angle, without presenting an undue opening that may increase the amount of cross contamination from one target to the next target. Generally speaking, this involves cutting a small section from the optional cutout that is just enough to allow a target tilted at its extreme tilt angle to pass through. By using innovative static shields 302 and 304 with optional cutouts 320 and 330 in the static shields, dynamic shields 210 and 212 may be kept smaller, which helps reduce the size of the target cover housing. Advantageously, this reduction in the target cover housing size allows the surface of the target cover housing to be brought closer to the targets to provide a greater clearance for wafer insertion.

As can be seen in FIG. 3, the static shields are also disposed vertically with respect to the rotational plane of the target assembly turret such that when target is indexed/rotated into position for sputtering, its two dynamic shields are aligned with the two static shields to form a larger shielding area, thereby minimizing cross contamination from target to target during the sputter deposition operation.

FIG. 4 shows, in accordance with an embodiment of the invention, relevant portions of the target assembly turret 402, source opening 404, and tilt-and-rotate fixture 406. The target cover housing is shown by reference number 410 and comprises surfaces 410A, 410B, 410C and 410D. This particular design of the target cover housing is only an example and other designs with a greater number or fewer number of surfaces are also possible. The static shields, which are shown as static shields 302 and 304 (see FIG. 3), may be attached to one or more of surfaces 410B, 410C or 410D of the example target cover housing 410 and may protrude toward the target turret assembly as shown.

In the drawing of FIG. 4, portions of static shield 302 and static shield 304 are shown.

Generally speaking, it is desirable to move surface 410C as far away from tilt-and-rotate fixture 406 as possible to facilitate wafer loading and unloading. However, when surface 410, for example, is brought closer to the target assembly turret, a large dynamic shield may Strike the inner surface 410C when the target assembly turret rotates and indexes its targets from position to position. By providing the static shields with optional cutouts, such as static shields 302 and 304, the dynamic shields (such as dynamic shields 210 and 212) may remain smaller such that when the target assembly turret rotates and dynamic shields 210 and 212 sweep rotationally, dynamic shields 210 and 212 do not impact or strike the inner surface of surfaces 410C, 410D or the opening in surface 410C and 410D.

As mentioned, optional cutouts (see 320 and 330 of FIG. 3) are provided to permit dynamic shields 210 and 212 to be smaller. If these optional cutouts (see reference numbers 320 and 330 of FIG. 3) were not provided, dynamic shields 210 and 212 would have to be made larger in order to prevent damage to extreme-tilt target 204 during indexing/rotation. By providing optional cutouts 320 and 330, the dynamic shields 210 and 212 may be made smaller, thereby allowing surfaces 410B, 410D and 410C to be brought closer to the target assembly turret and/or further away from tilt-and-rotate fixture 406 to facilitate wafer mounting and removal.

As can be appreciated from the foregoing, embodiments of the invention advantageously minimize cross contamination from target to target in a multi-target long throw deposition process. By using a combination of static and dynamic shields with optional cutouts, it is possible to permit the target assembly turret to freely rotate while keeping the target cover housing small and disposed further away from the tilt-and-rotate fixture and/or the plasma source to facilitate wafer mounting/removal.

While this invention has been described in terms of several preferred embodiments, there are alterations, permutations, and equivalents, which fall within the scope of this invention. For example, although the optional cutouts are shown with both static shield pieces, it is possible to further reduce the risk of cross-contamination by providing the optional cutout with only one of the two static shields if rotation is only in one direction (e.g., only clockwise or counter-clockwise) and there is no danger of target damage due to an extreme tilt angle when rotating past one of the static shields (which makes it possible to eliminate the optional cutout for that one static shield). This is the case if, for example, the targets are always stowed when not in use and rotating a stowed target into position for sputtering would not involve the risk of damaging that target since that target would not be in an extreme tilt position. It should also be noted that there are many alternative ways of implementing the methods and apparatuses of the present invention. Although various examples are provided herein, it is intended that these examples be illustrative and not limiting with respect to the invention. If the term “set” is employed herein, such term is intended to have its commonly understood mathematical meaning to cover zero, one, or more than one member.

What is claimed is:

1. A multi-target deposition arrangement, comprising:
a target assembly turret configured to be rotatable;
a plurality of targets mounted on said target assembly turret, wherein a first target is positioned in an operational position, wherein said operational position is facing a substrate during sputtering; and
a shield arrangement including at least
a set of static shields attached to said target assembly turret, and
a set of dynamic shields, wherein said set of dynamic shields is aligned with said set of static shields when said first target is rotated into said operational position for sputtering, wherein said shield arrangement prevents cross contamination to other targets when said sputtering is occurring to said first target.

2. The arrangement of claim 1 wherein said first target is pre-tilted at a predefined angle.

3. The arrangement of claim 1 wherein said first target is dynamically tilted.

4. The arrangement of claim 1 wherein said set of dynamic shields is configured to rotate along with said plurality of targets.

5. The arrangement of claim 4 wherein said set of dynamic shields is configured to be positioned vertically relative to a rotational plane of said target assembly turret.

6. The arrangement of claim 5 wherein said set of static shields is configured to be stationary relative to said target assembly turret.

7. The arrangement of claim 6 wherein said set of static shields is configured to be positioned vertically relative to said rotational plane of said target assembly turret.

8. The arrangement of claim 7 wherein a first static shield of said set of static shields include a plurality of flanges configured for fastening said first static shield to a surface of a first target cover housing.

9. The arrangement of claim 8 wherein said first target includes an optional cutout configured for enabling said first target to rotate without damaging said other targets when said first target is tilted at an extreme angle, wherein said extreme angle is such that a bottom of said first target protrudes beyond a plane formed by an edge of a first dynamic shield and a second dynamic shield, wherein said first dynamic shield and said second dynamic shield is positioned on each side of said first target.

10. The arrangement of claim 9 wherein a size of said optional cutout is dimensioned to provide clearance of said target assembly turret during said rotation without providing an opening large enough to enable said cross contamination.

11. A plasma processing system with a multi-target deposition arrangement, comprising:
a plasma source configured for at least generating a plasma during substrate processing;
a tilt-and-rotate fixture configured at least for mounting a substrate;
a target assembly turret configured to be rotatable, wherein said target assembly turret is configured to include a plurality of housings;
a plurality of targets, wherein each target of said plurality of targets is mounted on said target assembly turret within each housing of said plurality of housings, wherein a first target is positioned in an operational position, wherein said operational position is facing said substrate during sputtering; and
a shield arrangement configured to include
a set of static shields is attached to said target assembly turret, and
a set of dynamic shields, wherein said set of dynamic shields is aligned with said set of static shields when a first target is rotated into said stationary position for sputtering, wherein said shield arrangement prevents cross contamination to other targets when said sputtering is occurring to said first target.

12. The arrangement of claim 11 wherein said first target is pre-tilted at a predefined angle.

13. The arrangement of claim 11 wherein said first target is dynamically tilted.

14. The arrangement of claim 11 wherein said set of dynamic shields is configured to rotate along with said plurality of targets.

15. The arrangement of claim 14 wherein said set of dynamic shields is configured to be positioned vertically relative to a rotational plane of said target assembly turret.

16. The arrangement of claim 15 wherein said set of static shields is configured to be stationary relative to said target assembly turret.

17. The arrangement of claim 16 wherein said set of static shields is configured to be positioned vertically relative to said rotational plane of said target assembly turret.

18. The arrangement of claim 17 wherein a first static shield of said set of static shields include a plurality of flanges configured for fastening said first static shield to a surface of a first target cover housing.

19. The arrangement of claim 18 wherein said first target includes an optional cutout configured for enabling said first target to rotate without damaging said other targets when said first target is tilted at an extreme angle, wherein said extreme angle is such that a bottom of said first target protrudes beyond a plane formed by an edge of a first dynamic shield and a second dynamic shield, wherein said first dynamic shield and said second dynamic shield is positioned on each side of said first target.

20. The arrangement of claim 19 wherein a size of said optional cutout is dimensioned to provide clearance of said target assembly turret during said rotation without providing an opening large enough to enable said cross contamination.
